(19) United States
(12) Patent Application Publication
(10) Pub. No.: US 2026/0303110 A1
(43) Pub. Date: Oct. 1, 2026

(54) METHODS AND APPARATUS TO POSITION INTERLEAVED CONVERSION CIRCUITRY

(71) Applicant: Texas Instruments Incorporated, Dallas, TX (US)

(72) Inventors: Ankush Sharma, Bangalore (IN); Karthikeyan Gunasekaran, Chennai (IN); Raviprasad Kuloor, Bangalore (IN); Yokesh Pari, Bangalore (IN); Musala Reddy Syagamreddy, Bangalore (IN); Visvesvaraya Appala Pentakota, Bangalore (IN); Snehasish Roychowdhury, Dakshin Barasat (IN); Prajjwal Rana, Aligarh (IN)

(21) Appl. No.: 19/096,278

(22) Filed: Mar. 31, 2025

(51) Int. Cl. H03M 1/12; H03M 1/66

(52) U.S. Cl. CPC H03M 1/121; H03M 1/662

(57) ABSTRACT

An example integrated circuit includes: two or more conversion circuits that are implemented on one layer of the integrated circuit in a circular pattern around a center point of the layer; and interconnects between the two or more conversion circuits and the center point.

### TECHNICAL FIELD

This description relates generally to analog and digital conversion, and, more particularly, to methods and apparatus to position interleaved conversion circuitry.

### BACKGROUND

Interleaved conversion circuitry refers to an architecture where the signals generated by multiple conversion circuit modules are combined to produce a final result. For example, interleaved Digital to Analog Conversion (DAC) circuitry may be implemented by two or more DAC modules, where each individual DAC module is responsible for converting a different digital bit into an analog voltage. Similarly, interleaved Analog to Digital Conversion (ADC) circuitry may be implemented by two or more ADC modules, where each individual ADC module is responsible for converting a different portion of the analog voltage into a digital bit.

### SUMMARY

A first example integrated circuit includes: two or more conversion circuits that are implemented on one layer of the integrated circuit in a circular pattern around a center point of the layer, and interconnects between the two or more conversion circuits and the center point.

A second example integrated circuit includes: a ground plane on a first layer of the integrated circuit, two or more conversion circuits that are implemented on a second layer of the integrated circuit in a circular pattern around a center point of the second layer, the second layer beneath the first layer, and interconnects between the two or more conversion circuits and the center point.

An example apparatus includes: digital circuitry configured to produce first digital data, format circuitry configured to change the first digital data from a binary format to a thermometric format, cancellation circuitry configured to produce second digital data that a) does not have a bit transition wherever the first digital data does have a bit transition and b) does contain a bit transition wherever the first digital data does not have a bit transition, and interleaved Digital to Analog Conversion (DAC) circuitry configured to convert the first digital data and the second digital data into analog current signals, wherein the interleaved DAC circuitry is implemented on an integrated circuit that includes: two or more conversion circuits implemented on one layer of the integrated circuit in a circular pattern around a center point of the layer, and interconnects between the two or more conversion circuits and the center point.

### BRIEF DESCRIPTION OF THE DRAWINGS

FIG. 1 is a block diagram of an example environment that includes interleaved Digital to Analog Conversion (DAC) circuitry.

FIG. 2 is a profile view of a known approach to implement the interleaved DAC circuitry of FIG. 1.

FIG. 3 is an isometric view of an example integrated circuit (IC) that implements the interleaved DAC circuitry of FIG. 1 using the examples described herein.

FIG. 4 is a top-down view of a thick layer of the example IC shown in FIG. 3.

FIGS. 5A and 5B are top-down views of two thick layers of the example IC shown in FIG. 3.

FIG. 6 is a top-down view of the thin layer of the example IC shown in FIG. 3.

FIG. 7 is a block diagram of an example processing platform including programmable circuitry structured to execute, instantiate, or perform machine-readable instructions or perform operations to implement the device 100 of FIG. 1.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

The accuracy of interleaved conversion circuitry is largely dependent on timing. For example, suppose an interleaved DAC circuitry formed by x DAC modules has an output coupled to a load. Suppose further that the load is part of a use case or application that expects the output of the interleaved DAC circuitry to update by the timestamp T₀. In such an example, an accurate analog voltage is the sum of: the analog voltage produced by DAC module #1 at T₀, plus the analog voltage produced by DAC module #2 at T₀, . . . , plus the analog voltage produced by DAC module #x at T₀. Accordingly, if (x-1) of the DAC modules produce their respective analog voltages by T₀ but the xth DAC module is late, then the entire output of the interleaved DAC circuitry is inaccurate. As used herein, error caused by inaccurate timing in one or more components of interleaved conversion circuitry is referred to as mismatch.

Interleaved conversion circuits support a level of timing accuracy (and therefore a level of conversion accuracy) by implementing clock buffer circuitry so that a first conversion module of the interleaved circuitry receives the requisite signals at its inputs, and a second conversion module of the interleaved circuitry receives the requisite signals at its inputs, within a threshold amount of time from one another. However, the number of clock buffer circuits required to implement the interleaved conversion circuitry is dependent on the architecture in which the conversion modules are physically located on an integrated circuit (IC). More generally, the amount of area, the cost, and the performance of interleaved conversion circuitry is dependent on where the conversion modules are physically located on an IC relative to one another.

Known interleaved conversion circuitry is implemented using a linear architecture. As used herein, a linear architecture refers to when conversion modules of interleaved conversion circuitry are located adjacent to one another on an IC and collectively resemble the shape of a line. Linear architectures provide a logical mapping between the physical placement of the conversion modules and a data structure (for example, an array, a buffer, a vector, a list, etc.) used to represent the conversion modules. For example, in a linear architecture, a DAC module responsible for converting the first most significant bit (MSB) corresponds to the first index of the data structure and is physically located at the left-most position on the IC. Next, the DAC module responsible for the second MSB corresponds to the second index of the data structure and is physically located on the IC directly adjacent to the DAC module that converts the first MSB, etc.

While linear architectures logically position the interleaved modules on an IC, the positioning requires a comparatively large amount of space and cost to implement. The linear positioning also introduces dynamic error that limits the performance of the interleaved conversion circuitry. As used above and herein, dynamic error refers to a type of error whose magnitude changes at runtime. Therefore, a compute device cannot preemptively compensate for dynamic error in its design. In contrast, because static errors can be calculated before runtime, the designs of compute devices generally compensate for the static error so it does not affect runtime performance.

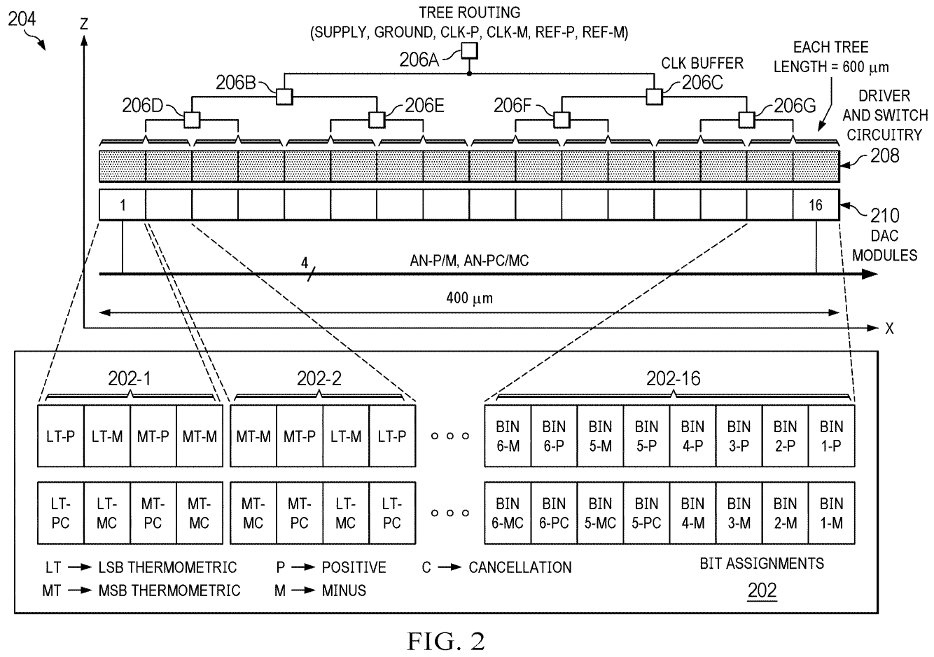

The performance of known linear architectures is limited by significant dynamic error. For example, the linear architecture requires multiple interconnect tree structures to deliver the data and other requisite signals (for example, clock signals, supply voltages, etc.) to the respective DAC or ADC modules. Such tree structures require a large amount of three-dimensional space to reach each of the DAC or ADC modules without interfering with one another. The difference in the length of tree structures adds mismatch that introduces dynamic error and negatively affects performance. The multiple tree structures also requires multiple clock buffers to implement, which each take space, consume power, and add noise to the system. More generally, the performance, cost, and size of known interleaved conversion circuitry is limited by their linear architecture implementation. Linear architectures of known interleaved conversion circuitry are described further in connection with FIG. 2.

Example methods, apparatus, and systems described implement a radial architecture in which two or more conversion circuits of interleaved conversion circuitry are physically located on an IC in a pattern that resembles a circle. The conversion circuits are physically located closer to one another in the example radial architecture than they are in the linear architecture, thereby reducing mismatch. Instead of implementing interconnects in tree structures, the supply voltage and clock signals required for the conversion circuits to produce an output are routed through the center of the circular pattern, thereby ensuring the interconnects are equal in length to one another and further reducing mismatch. The lack of tree structures in the example radial architecture significantly reduces the number of clock buffer circuits, thereby reducing the power consumption and noise produced by the example radial architecture when compared to the linear architecture. The lack of tree structures also enables the interleaved conversion modules to access ground and reference signals on a separate layer over the conversion modules, thereby reducing the rise and fall times when the output of the conversion circuitry updates. More generally, by eliminating dynamic error, the radial architecture described herein is implemented with less area, consumes less power, and performs better than known interleaved conversion circuitry.

In some examples, the two or more conversion circuits collectively form interleaved Digital to Analog Conversion (DAC) circuitry. In other examples, the two or more conversion circuits collectively form interleaved Analog to Digital Conversion (ADC) circuitry. As used above and herein, the terms “conversion circuits” and “conversion modules” may be used interchangeably. Similarly, a conversion module may be implemented by either a DAC module or an ADC module.

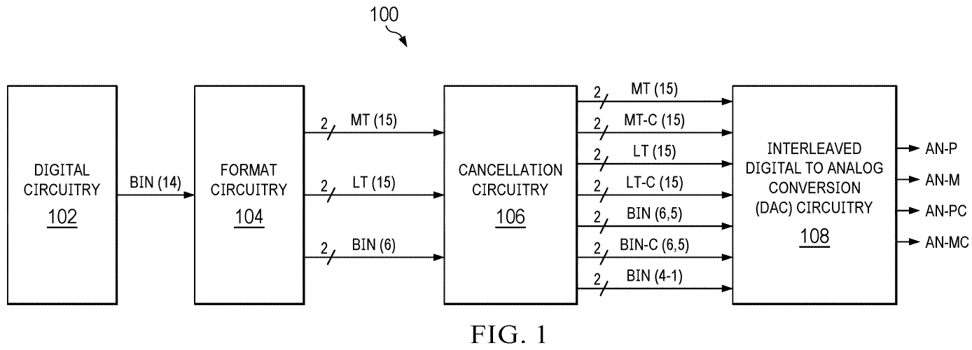

FIG. 1 is a block diagram of an example device that includes interleaved Digital to Analog Conversion (DAC) circuitry. The device 100 of FIG. 1 includes example digital circuitry 102, example format circuitry 104, example cancellation circuitry 106, and example interleaved DAC circuitry 108. The device 100 of FIG. 1 may be instantiated (for example, creating an instance of, bring into being for any length of time, materialize, implement, etc.) by programmable circuitry such as a Central Processor Unit (CPU) executing first instructions. Also or alternatively, the device 100 of FIG. 1 may be instantiated (for example, creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 1 may, thus, be instantiated at the same or different times. Some or all of the circuitry of FIG. 1 may be instantiated, for example, in one or more threads executing concurrently on hardware or in series on hardware. Moreover, in some examples, some or all of the circuitry of FIG. 1 may be implemented by microprocessor circuitry executing instructions or FPGA circuitry performing operations to implement one or more virtual machines or containers.

The digital circuitry 102 refers to any device that produces digital data. The digital data may correspond to any use case or application. In this example, the digital circuitry 102 generates the digital data in units of fourteen binary bits. In other examples, the digital circuitry 102 generates the digital data in different units.

The digital circuitry 102 may be implemented using any type of programmable circuitry. Examples of programmable circuitry include but are not limited to programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs).

The format circuitry 104 converts a portion of the data produced by the digital circuitry 102 from the binary format into thermometric format. As used above and herein, thermometric refers to a data format in which a natural number n is represented by n consecutive bits of the same value, followed by one bit of the other value. For example, the number 5 is represented in binary as 101 (as 4+1=5), but is represented in thermometric as 111110 (as 1+1+1+1+1=5). By representing the digital data in the thermometric format, the format circuitry 104 enables the interleaved DAC circuitry 108 to express differences in the digital value using less current than is necessary for the binary format. For example, suppose the digital circuitry 102 produces a first digital value of 710 and a second digital value of 810. Suppose further that the transition between two adjacent natural numbers requires at least 16 microamps (μA) for ADC circuitry to distinguish the two values. In such an example, expressing such a change in binary (for example, updating the output from 0111_{bin} to 1000_{bin}) requires of a total of 240 μA to change because turning the bit in the 8′s position to a logical ‘1’ requires 128 μA, and turning the bits in the 4's, 2's, and 1's position to a logical ‘0’ requires 64 μA, 32 μA, and 16 μA respectively. In contrast, expressing the same change in thermometric (for example, updating the output from 011111110ₜₕₑᵣₘ to 111111110ₜₕₑᵣₘ) only requires 16 μA because there is only one transition and all transitions in thermometric formatting are represented by the minimum amperage (16 μA of this example). All thermometric bit transitions can be represented by the same change in current because, unlike binary, thermometric bit positions are unweighted. Furthermore, each transition that occurs in digital data can introduce an amount of error. For example, despite receiving a digital data transition at its input that converts to a change of 16.0 μA in the analog domain, the actual change in current produced by the DAC module may be anywhere between approximately 15.5 μA and 16.5 μA. Thus, reducing the number of digital transitions for conversion increases the accuracy of the interleaved DAC circuitry 108.

In the example of FIG. 1, the format circuitry 104 converts the four MSBs of the binary data into fifteen differential thermometric bits. The foregoing data is collectively labelled in FIG. 1 as the Most significant Thermometric (MT) bits, where the positive components of the differential signal are labeled MT-P and the minus components of the differential signal are labeled MT-M. The format circuitry 104 also converts the next four MSBs of the binary data into another fifteen thermometric bits. The foregoing data is collectively labelled in FIG. 1 as the Least significant Thermometric (LT) bits, where the positive components of the differential signal are labeled LT-P and the minus components of the differential signal are labeled LT-M. In this example, the format circuitry 104 converts the last six binary bits into differential data having positive and minus components but does not convert the last six binary bits to thermometric. In other examples, the cancellation circuitry 106 converts a different amount of digital data from binary to thermometric.

In the example of FIG. 1, the interleaved DAC circuitry 108 is expected to consume the same amount of power and exhibit the same kickback noise regardless of the values within the digital data provided by the digital circuitry 102. However, both the amount of power consumed by the interleaved DAC circuitry 108 and the signal kickback can change whenever a bit transition occurs (for example, the bit position updates from a 0 to 1 or from a 0 to 1). Accordingly, the cancellation circuitry 106 creates differential MT cancellation signals (labelled herein as MT-C) such that, for any two consecutive bits, a transition occurs in the MT-C signals whenever the MT signals do not transition and vice versa. The cancellation circuitry 106 also creates differential LT cancellation signals (labelled herein as LT-C) such that, for any two consecutive bits, a transition occurs in the LT-C signals whenever the LT signals do not transition and vice versa. By converting both the primary thermometric bits and the cancellation thermometric bits into analog values, the interleaved DAC circuitry 108 maintains the same transient activity regardless of the data pattern. In this example, the cancellation circuitry 106 also generates cancellation bits for the fifth and sixth LSBs of the remaining binary data but does not generate cancellation bits for the first four LSBs of the remaining binary data.

The interleaved DAC circuitry 108 converts the MT data, the MT-C data, the LT data, the LT-C data, the remaining binary data, and the binary cancellation data into four separate analog (abbreviated in the figures herein as AN) current signals. To do so, the interleaved DAC circuitry 108 includes multiple DAC modules that each produce four current signals. The current signals from the individual DAC modules are then added together to produce the AN-P, AN-M, AN-PC, and AN-MC current signals. In this example, the AN-P and AN-M currents are the two components of a primary differential analog current signal that, when interpreted together, represent the analog equivalent of the digital data produced by the digital circuitry 102. Similarly, the AN-PC and the AN-MC currents are the two components of a differential cancellation signal. The interleaved DAC circuitry 108 generates the differential cancellation signal to maintain transient activity as described above.

The interleaved DAC circuitry 108 receives digital data and converts it into the four current signals at a very high frequency. To support these high frequency operations, the interleaved DAC circuitry 108 has a very low tolerance for dynamic error and third order intermodulation distortion (IMD3). For example, in the examples described herein, the interleaved DAC circuitry 108 operates at 32 Gigasamples per second (Gsps). To support this speed, the MSB mismatch caused by dynamic error has a required limit of 1.97 fs. The interleaved DAC circuitry 108 described in the examples below also targets an IMD3 measurement of 80 decibels relative to the carrier (dBc) at −6 decibels relative to full scale (dBFs). In other examples, the interleaved DAC circuitry 108 operates at a different speed and has a different tolerance for dynamic error.

When referencing at least one of a semiconductor device, for example, a transistor, a semiconductor die containing a semiconductor device, or an integrated circuit (IC) package containing a semiconductor die during fabrication or manufacturing, “over”, “beneath”, and “below” are not with reference to Earth, but instead are with reference to an underlying substrate from which relevant components are fabricated, assembled, mounted, supported, or otherwise provided. Thus, as used herein and unless otherwise stated or implied from the context, a first component within a semiconductor die, for example, a transistor or other semiconductor device, is “over” a second component within the semiconductor die when the first component is farther away from a substrate, for example, a semiconductor wafer, during fabrication/manufacturing than the second component on which the two components are fabricated or otherwise provided. Semiconductor devices are often used in orientation different than their orientation during fabrication. A first part can be over or below a second part with one or more of: other parts therebetween, without other parts therebetween, with the first and second parts touching, or without the first and second parts being in direct contact with one another. Similarly, as used herein and unless otherwise stated or implied from the context, “up”, “upwards”, and similar terms refer to a direction that points away from a substrate layer, while “down”, “downwards”, and similar terms refer to a direction that points towards a substrate layer. As used in this patent, stating that any part (for example, a layer, film, area, region, or plate) is in any way on (for example, positioned on, located on, disposed on, or formed on, etc.) another part, indicates that the referenced part is either in contact with the other part, or that the referenced part is above the other part with one or more intermediate part(s) located therebetween.

FIG. 2 is a profile view of a known approach to implement the interleaved DAC circuitry of FIG. 1. FIG. 2 includes bit assignments 202-1, 202-2, . . . , 202-16 (collectively referred to as bit assignments 202). FIG. 2 also includes a cross-profile view of an integrated circuit (IC) 204. The cross-profile view is on an X-Z plane where increasing in the Z dimension indicates moving both upwards and further away from a substrate layer. In keeping with the usage of the terms “over” and “below” throughout this patent, a component with a higher Z value is considered over a component with a lower Z value. The IC 204 includes clock buffer circuitry 206A, 206B, . . . , 206G, driver and switch circuitry 208, and DAC module circuitry 210-1, 210-2, . . . , 210-16 (collectively referred to as DAC modules 210).

The bit assignments 202 show how the data from the cancellation circuitry 106 (for example, the MT data, the MT-C data, the LT data, the LT-C data, the binary data, and the binary cancellation data as described in FIG. 1) is distributed amongst the sixteen DAC modules 210. In other use cases, the IC 204 implements the interleaved DAC circuitry 108 using a different number of DAC modules 210. The bit assignments 202 show that each of the DAC modules 210-1-210-15 convert eight digital values into analog currents concurrently. The bit assignment 202-1 shows the DAC module 202-1 receives one of the LT-P bits, one of the LT-M bits, one of the MT-P bits, one of the MT-M bits, one of the LT-PC bits, one of the LT-MC bits, one of the MT-PC bits, and one of the MT-MC bits. The bit assignment 202-2 shows the DAC module 210-2 receives bits from the same eight data streams as the DAC module 210-1, but in a different order. The bit assignment 202-3 then matches the same data streams and the same order as the bit assignment 202-1. Similarly, the bit assignment 202-4 matches the same data streams and the same order as the bit assignment 202-2, etc. This pattern continues through the DAC module 210-15, whose corresponding bit assignment 202-15 matches the same data streams and the same order as the bit assignments 202-1, 202-3, 202-5, 202-7, 202-9, 202-11, and 202-13.

The bit assignment 202-16 shows that the DAC module 210-16 converts the positive and minus portions of the fifth and sixth indexed binary LSBs (labeled as BIN 5 and BIN 6 in FIG. 2), as well as their corresponding cancellation bits, concurrently. The DAC module 210-16 also converts the positive and minus components of the first through fourth indexed binary LSBs (labeled as BIN 4 through BIN 1 in FIG. 2) concurrently with BIN 5 and BIN 6. The DAC module 210-16 may be implemented with a greater number of components than any of the individuals DAC modules 210-1-210-15 to support a greater number of simultaneous conversion operations. However, the DAC module 210-16 consumes approximately the same amount of power as the other DAC modules 210-1-210-15 because the bit assignments 202-16 contain the least significant bits and therefore correspond to the smaller amperages than other bit conversions.

The IC 204 distributes data from the cancellation circuitry 106 to the DAC modules 210 responsive to the bit assignments 202. Upon receiving the data, the DAC modules 210 perform convert the digital bits into analog currents and transmit the current onto one of four outputs. For example, the first outputs of all the DAC modules 210 are coupled together and the total current on the resulting electrical node forms the AN-P signal described above. The DAC modules 210-1-210-15 each provides a) current that corresponds to the LT-P bit and b) current that corresponds to the MT-P bit at their first outputs to contribute to the AN-P signal. The DAC module 210-16 also contributes to the AN-P signal by providing current that corresponds to the BIN 6-P, BIN 5-P, BIN 4-P, BIN 3-P, BIN 2-P, and BIN 1-P bits at its first output.

The second outputs of all the DAC modules 210 are also coupled together and the total current on the resulting electrical node forms the AN-M signal described above. The DAC modules 210-1-210-15 each provide a) current that corresponds to the LT-M bit and b) current that corresponds to the MT-M bit at their second outputs to contribute to the AN-M signal. The DAC module 210-16 also contributes to the AN-M signal by providing current that corresponds to BIN 6-M, BIN 5-M, BIN 4-PM BIN 3-M, BIN 2-M, and BIN 1-M bits at its second output.

The third outputs of all the DAC modules 210 are also coupled together and the total current on the resulting electrical node forms the AN-PC signal described above. A given DAC module circuitry 210-1-210-15 each provide a) current that corresponds to the LT-PC bit and b) current that corresponds to the MT-PC bit at their third outputs to contribute to the AN-PC signal. The DAC module 210-16 also contributes to the AN-PC signal by providing current that corresponds to the BIN 6-PC and BIN 5-PC at its third output.

The fourth outputs of all the DAC modules 210 are also coupled together and the total current on the resulting electrical node forms the AN-MC signal described above. A given DAC module circuitry 210-1-210-15 each provide a) current that corresponds to the LT-MC bit and b) current that corresponds to the MT-MC bit at their fourth outputs to contribute to the AN-MC signal. The DAC module 210-16 also contributes to the AN-MC signal by providing current that corresponds to BIN 6-MC and BIN 5-MC at its fourth output.

The cross-profile view of FIG. 2 shows that the IC 204 implements the interleaved DAC circuitry 108 using a known linear architecture that spans approximately 400 micrometers (μm) in length (for example, across the x-dimension). In the linear architecture, the IC 204 routes some signals necessary for conversion operations to the clock buffer circuitry 206A, which is physically implemented over the DAC modules 210 and approximately in the middle of the 400 μm x axis of FIG. 2. As used above and herein, clock buffer circuitry accepts a signal at its input and distributes multiple copies of the signal at its outputs. In doing so, clock buffer circuitry also mitigates against factors that degrade signal quality (for example, parasitic capacitance) that increase proportionally with transmission distance.

The IC 204 includes interconnects that, from the clock buffer circuitry 206A, branch in two directions. The first branch moves left in the x dimension before moving downwards in the z dimension. The second branch moves right in the x dimension for the same distance as the first branch and then downwards in the z dimension for the same distance as the first branch. After the downwards traversal, the length of each branch is already long enough that the parasitic capacitance risks degrading the quality of the signal below an acceptable threshold. Accordingly, the IC 204 terminates the left branch into clock buffer circuitry 206B and the terminates the right branch into clock buffer circuitry 206C. The clock buffer circuitry 206B and 206C both have two outputs coupled to two new branches of interconnects. The new interconnects follow the same pattern: starting at a given clock buffer, one branch travels to the left, one branch travels to the right by the same distance, and both branches travel downwards by the same distance. To maintain signal integrity, each of the four branches then terminate at four additional clock buffer circuits 206D, 206E, 206F, and 206G. Finally, the IC 204 has interconnects that start at the outputs of each of the clock buffer circuits 206D, 206E, 206F, and 206G, branch in the foregoing pattern, and terminate at the driver and switch circuitry 208. The driver and switch circuitry 208 restores the signals before providing the values to the DAC modules 210. As used herein, the foregoing series of interconnects is described as a tree structure. In FIG. 2, the driver and switch circuitry 208 also provides data from the cancellation circuitry 106 to the DAC modules 210 without the use of a tree structure.

Notably, the tree structure is symmetric such that the total length of interconnects from the clock buffer circuitry 206A to the DAC module circuitry 210-16 (600 μm in FIG. 2) is the same as the total length of interconnects from the clock buffer circuitry 206A to any of the other DAC modules 210A, 210B, etc. Thus, the IC 204 is designed so that signals from the clock buffer circuitry 206A arrive to all the DAC modules 210 simultaneously to avoid timing errors. However, the tree structure requires multiple clock buffer circuit to implement, each of which require additional space on the IC 204 to implement, consume additional power, and add noise to the system. Furthermore, the width of the interconnects at the top of the tree structure is required to be relatively large because the interconnects transmit a large portion of the total amount of the signal. The relatively wide interconnects require additional space within the IC 204 and cost extra to implement compared to relatively narrower interconnects that are responsible for carrying less information.

While the presence of a single tree structure limits the perfoamnce of the interleaved DAC circuitry 108, the known linear architecture shown in FIG. 2 requires multiple tree structures to implement. To successfully convert the digital data into an analog current, the IC 204 implements a separate interconnect tree structure to provide each of a supply voltage, a ground voltage, a differential clock signal (whose component parts are labeled in the figures herein as CLK-P and CLK-M), and a differential reference signal (whose component parts are labeled in the figures herein as REF-P and REF-M) to the IC 204.

In FIG. 2, the multiple tree structures of the IC 204 are implemented at various positions in the y dimension. More generally, known linear architectures may implement tree structures both over and below the DAC modules 210, thereby significantly increasing the amount of space required to implement the linear architecture. The presence of multiple symmetrical tree structures that start at different positions but arrive at the same destination adds significant design complexity and clogs the space over and below the DAC modules 210 with interconnects. Furthermore, while each tree structure is designed to be the same distance from the source to the destination (600 μm in FIG. 2), some tree structures will be longer than others due to the limited space over and below the DAC modules 210. This difference in interconnect length adds mismatch which contributes to dynamic error as described above. Furthermore, the signal routing introduces harmonic distortion wherever interconnects from two different tree structures cross one another. Thus, the IC 204 of FIG. 2 is unable to meet the 1.97 fs dynamic error tolerance or the 80 dBc at −6 dBFs target of the interleaved DAC circuitry 108 described above in the example of FIG. 1. More generally, in addition to requiring significant space on an IC, cost, and complexity to implement, the known linear architecture also limits performance such that interleaved conversion circuitry implemented with a linear architecture may be unable to support high frequency use cases.

In FIG. 2, the AN-P, AN-M, AN-PC, and AN-MC current signals IC 204 exit the IC 204 by using interconnects that travel downwards in the z dimension without the use of a tree structure. A naïve approach to match the settling time of the interleaved DAC circuitry modifies the linear architecture of FIG. 2 by adding interconnect tree structures that couple to the outputs of the DAC modules 210 for the current signals, the supply voltage, and the REF signals that. The new interconnect tree structures of the naïve approach mirror the preexisting tree structures coupled to the inputs of the DAC modules 210 in both size and positioning. Theoretically, the including on the additional tree structures adds latency after the outputs of the DAC modules 210 that is equal in magnitude to the latency exhibited before the inputs of the DAC modules 210, thereby reducing settling time. However, the naïve approach also doubles the amount of interconnect routing required to implement the interleaved DAC circuitry 108. The additional interconnect routing adds additional cost, complexity, and space to the design of the IC 204, increases propagation delay, limits bandwidth, and decreases transient response performance. Thus, neither the linear architecture shown in FIG. 2 nor the naïve modification of the linear architecture described meets the performance requirements of high frequency interleaved conversion circuitry in a cost effective and space efficient manner.

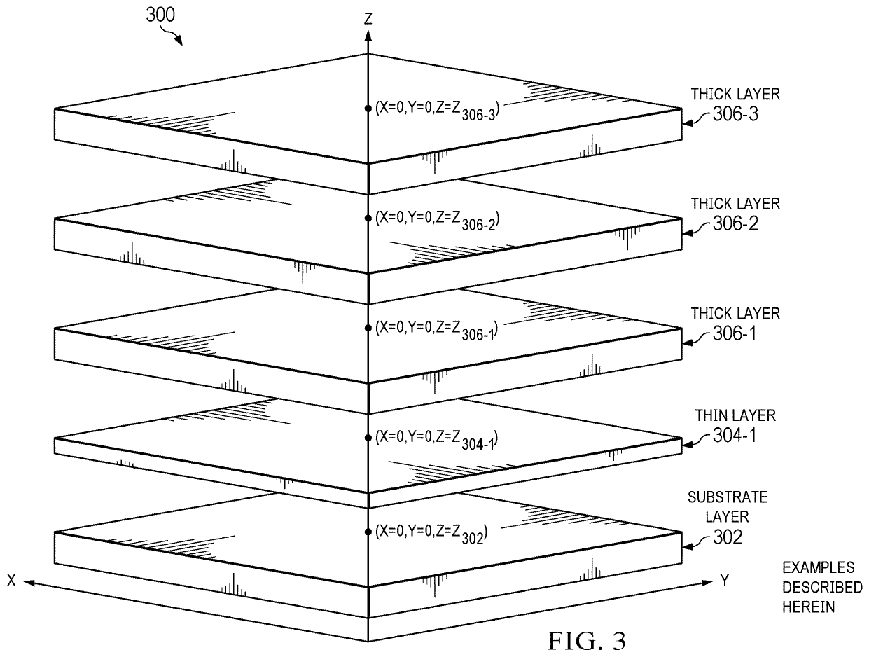

FIG. 3 is an isometric view of the interleaved DAC circuitry of FIG. 1 when implemented as described in the examples herein. The IC 300 of FIG. 3 includes an example substrate layer 302, an example thin layer 304-1, and example thick layers 306-1, 306-2, and 306-3 (collectively referred to as thick layers 306). As used above and herein, a layer of an IC refers to a three-dimensional region that varies in the x and y dimensions but is constant and uniform in the z dimension. Accordingly, multiple components and materials may be implemented within a single layer of an IC. Furthermore, components and materials within the same layer exist at the same depth, while components and materials from different layers are positioned over or beneath one another. The values Z₃₀₂, Z₃₀₄₋₁, Z₃₀₆₋₁, Z₃₀₆₋₂, and Z₃₀₆₋₃ represent the z values at the top surfaces of the substrate layer 302, the thin layer 304-1, and the thick layers 306-1, 306-2, and 306-3, respectively.

The examples of FIGS. 3-6 refer to the IC 300 in three dimensional coordinate space. Like the coordinate systems described above, an increase in the Z dimension of FIGS. 3-6 indicates moving both upwards and further away from the substrate layer 302. For example, the value of Z₃₀₆₋₃ is greater than the value of Z₃₀₆₋₂, and the thick layer 306-3 is considered over the thick layer 306-2, because the thick layer 306-2 is closer to the substrate layer 302 than the thick layer 306-3. In keeping with the usage of the terms “over” and “below” throughout the examples described herein, the substrate layer 302 is considered at or near the bottom of the IC 300 while the thick layer 306-3 is considered at or near the top of the IC 300.

Within the IC 300, the substrate layer 302 acts as a structural foundation that other parts of the IC 300 are built over during fabrication. In the example of FIG. 3, the substrate layer 302 is implemented with silicon. In other examples, the substrate layer 302 is implemented using a different type of semiconductive material. In some examples, one or more components of the IC 300 use the substrate layer 302 as a ground plane.

The thin layer 304-1 is implemented over the substrate layer 302 and beneath the thick layers 306. The thin layer 304-1 is referred to as thin in the examples described herein because distance (in the z dimension) between the top and bottom surfaces of the thin layer 304-1 is less than the distance between the top and bottom surfaces of any of the thick layers 306-1, 306-2, and 306-3 (for example, the thin layer 304-1 is less thick than any of the thick layers 306). In this example, the thin layer 304-1 is implemented using copper. In other examples, the thin layer 304-1 is implemented using one or more different type(s) of semiconductive materials, including but not limited to aluminum. The IC 300 is implemented with at least one thin layer 304-1 (as shown in FIG. 3), and may also be implemented with multiple thin layers, between the substrate layer 302 and the thick layers 306.

The thick layers 306 are implemented over the thin layer 304-1. The thick layers 306 are also thicker than thin layer 304-1 as described above. The extended length (in the z dimension) means the thick layers 306 require additional material to implement, but can also carry a greater amount of current, than the thin layer 304-1. In this example, the thick layers 306-3 is with an Aluminum Copper (AlCu) alloy while the thick layers 306-2 and 306-1 are implemented with copper. In other examples, one or more of the thick layers 306-1, 306-2, or 306-3 are implemented using one or more different type(s) of semiconductive materials. In some examples, the IC 300 implements one or more additional layers between a) the thick layer 306-1 and the thick layer 306-2 or b) the thick layer 306-2 and the thick layer 306-3.

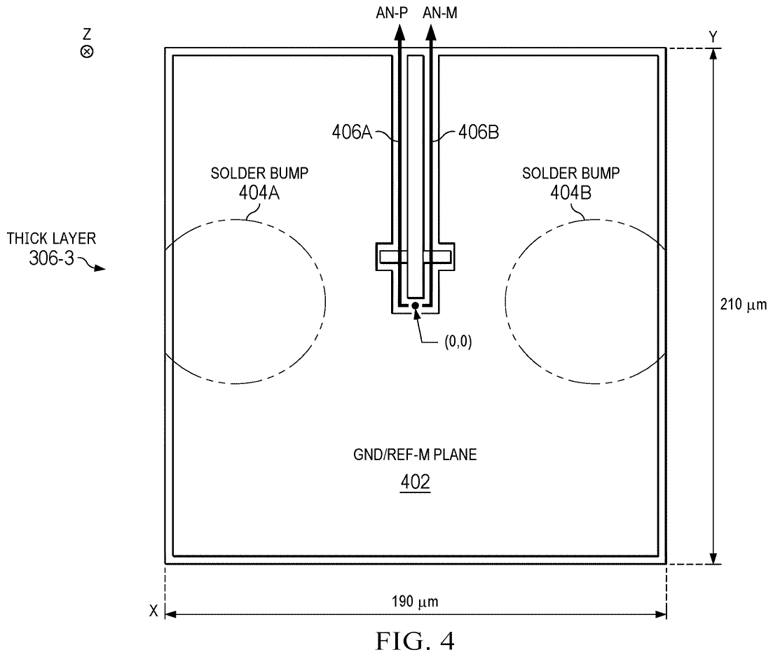

FIG. 4 is a top-down view of the thick layer 306-3 of FIG. 3. Accordingly, FIG. 4 shows an XY plane that only includes components that are implemented within the thick layer-FOR 306-3. FIG. 4 shows the thick layer 306-3 includes an example GND/REF-M plane 402, example solder bumps 404A and 404B, and example interconnects 406A and 406B (collectively referred to as interconnects 406).

The GND/REF-M plane 402 refers to a region of metal in the thick layer 306-3 that carries the same voltage at all points. In this example, the DAC modules use said voltage for both the ground signal and the minus component of the differential REF signal. In contrast, the DAC modules in the linear architecture of FIG. 2 require separate voltages from ground (abbreviated above and herein as GND) and REF-M because the large length of an interconnect structure amplifies changes in the REF-M value whenever a circuit coupled to GND performs operations.

In examples herein, the GND/REF-M plane 402 is implemented over the DAC modules as described further below. The examples described herein also implement the interleaved DAC circuitry 108 without any tree structures. Thus, the IC 300 electrically couples the DAC modules to the GND/REF-M plane 402 by using short, vertical interconnects that physically connect the thick layer 306-2 (the location of the DAC modules) to the thick layer 306-3 (the location of the GND/REF-M plane 402).

In contrast, the IC 204 cannot implement a GND plane because fabrication of a signal plane generally occurs on a region that is approximately equal in size for both the x and y dimensions (for example 190 μm×210 μm in the example of FIG. 4). However, the linear architecture implements DAC modules such that the region is disproportionately longer in one dimension than the other (for example, more rectangular than square). Fabricating such a unique plane is infeasible due to the added cost and complexity such a design requires. Moreover, the known linear architecture has multiple interconnect tree structures that congest the space over the DAC modules 210 and do not leave room to implement a GND plane.

Rather than using a plane as shown in FIG. 4, known linear architecture use interconnect tree structures to connect the DAC modules to GND and REF-M as shown in FIG. 2. The foregoing tree structures are longer than the interconnects between the thick layers 306-3 and 306-2. Thus, the example IC 300 described herein has a transient response that is approximately four times better than the known IC 204 because the distance travelled by an updated signal (for example, from the cancellation circuitry 106, to the DAC modules, and then to GND) is smaller in the IC 300 than it is in the IC 204.

The GND/REF-M plane 402 receive and distribute the GND and REF-M signal by electrically coupling to an external device (for example, a motherboard) via the solder bumps 404. The solder bumps 404 also physically connect the IC 300 to the external device.

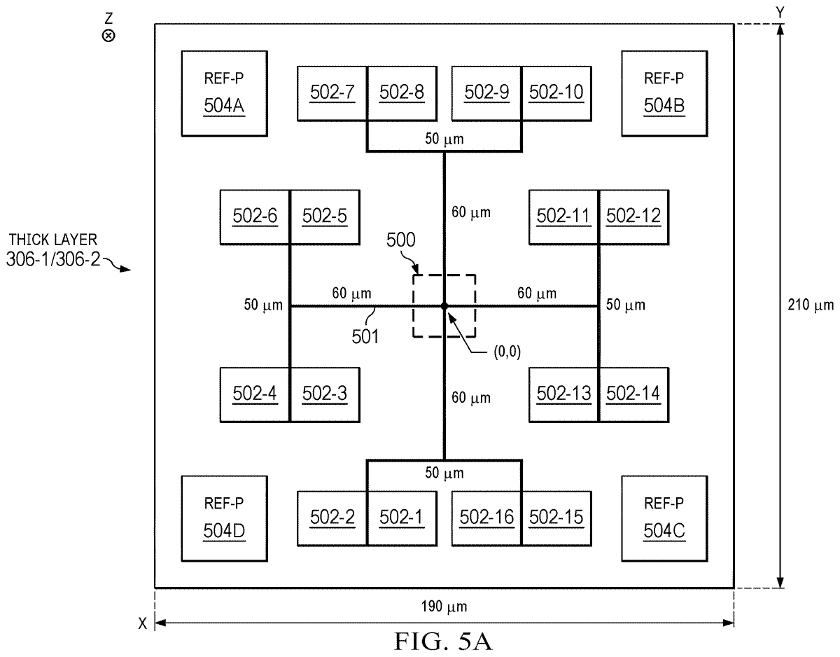

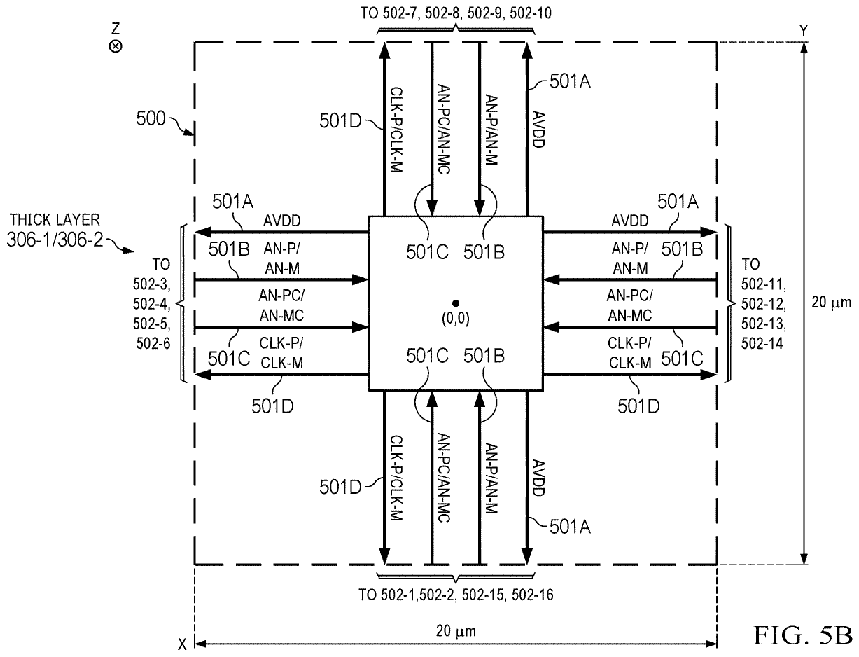

The interconnects 406 couples outputs of DAC modules to outputs of the IC 300. For example, the interconnect 406A carries the AN-P signal from a point at or near the center (for example, x=0, y=0) of the thick layer 306-3 to an output terminal of the IC 300. Similarly, the interconnect 406B carries the AN-M signal from a point at or near the center of the thick layer 306-3 to an output terminal of the IC 300. The interconnects 406 are implemented in the same layer as, but are electrically isolated from, the GND/REF-M plane 402. The signal routing from the DAC modules at layer 306-2 to the interconnects 406 is described further in connection with FIGS. 5A and 5B.

The output terminals of the IC 300 shown in FIG. 4 area configurable to be coupled to any external device for any suitable purpose. Such purposes include but are not limited to transmitting the differential analog signal over a medium, interpreting the differential analog signal to recreate the digital data, etc.

FIGS. 5A and 5B are top-down views of the thick layer 306-1 and the thick layer 306-2 shown in FIG. 3. Accordingly, the views of FIGS. 5A and 5B only components that are implemented in one or both of the thick layers 306-1 and 306-2. FIG. 5A includes an example region 500, example interconnects 501, example DAC module circuitry 502-1, 502-2, . . . , 502-16 (collectively referred to as DAC modules 502), and example REF-P circuits 504A, 504B, 504C, 504D (collectively referred to as the REF-P circuits 504). FIG. 5B shows the region 500 and shows the interconnects 501 includes example interconnects 501A, 501B, 501C, and 501D.

The DAC modules 502 collectively form the interleaved DAC circuitry 108 and individually convert digital data from the cancellation circuitry 106 into analog currents as described above. In this example, the DAC modules 502 of FIG. 5A have the same number of modules (sixteen) as the DAC modules 210 of FIG. 2. The DAC modules 502 also share the same bit assignments 202 as the DAC modules 210. However, the DAC modules 210 are implemented in the known linear architecture described above while the DAC modules 502 are implemented in an example radial architecture described herein. FIG. 5A shows that in the radial architecture, the DAC modules 502 are positioned symmetrically around a center point in both the x and y dimensions. Accordingly, the radial architecture resembles a circle from a top-down view as shown in FIG. 5A. FIG. 5A also shows that DAC modules in a radial architecture are located approximately the same distance from the center point (x=0, y=0).

FIGS. 5A and 5B collectively shows that, within the interconnects 501, the interconnects 501A and 501D provide the supply voltage (AVDD) and differential CLK signals, respectively, from the approximate center of the thick layer 306-1 to the DAC modules 502. The DAC modules 502 use both the supply voltage and the CLK signals when performing conversion operations. The conversion operations produce the AN-P, AN-M, AN-PC, and AN-MC currents at the outputs of the DAC modules 502. The interconnects 501B carry the AN-P and the AN-M signals from the outputs of the DAC modules 502 to a point at or near the center point of the thick layer 306-2. From the central position, the interconnects 501B then travel upward and couple to the interconnects 406A and 406B described above in connection with FIG. 4. The interconnects 501C also carry the AN-PC and the AN-MC signals from the outputs of the DAC modules 502 to a point at or near the center point of the thick layer 306-2. The interconnects 501C then terminate at or near the center point because unlike the AN-P and AN-M signals, the AN-PC and AN-MC signals are only implemented on internal nets and do not leave the IC 300. Accordingly, an external component can interpret the AN differential signal and recover digital data without the cancellation signals.

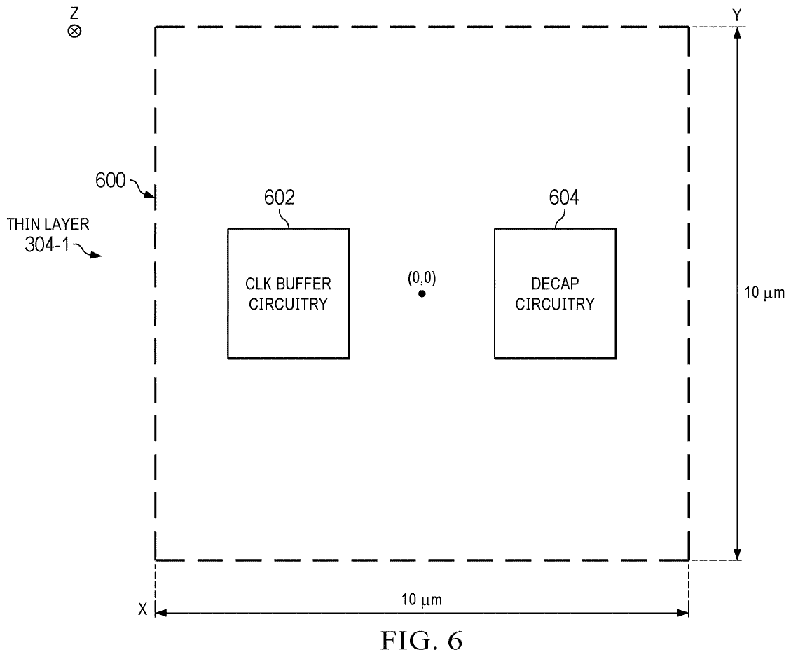

Advantageously, the shape and positioning of the radial architecture ensures that the portion of the interconnects 501 that connects the center point to a given DAC module circuitry 502-1 is the same length (for example, 110 μm in FIG. 5A) as the portion of the interconnects that connect the center point to any other DAC module circuitry 502-2, 502-3, 502-4, 502-5, 503-6, 502-7, 502-8, 502-9, 502-10, 502-11, 502-12, 502-13, 502-14, 502-15, or 502-16. Thus, the parasitic capacitance of the interconnects 501 is identical in all directions and the latency introduced by the interconnects 501 is identical for all DAC modules 502. Moreover, the dynamic error caused by mismatch in the radial architecture is greatly reduced compared to the dynamic error in the known linear architecture. The performance, size, and cost of the radial architecture described herein is described further in connection with FIG. 6.

In this example, the DAC modules 502 and the REF-P circuits 504, are implemented on one layer (the thick-layer 306-2), while the interconnects 501 are implemented across two layers (the thick layers 306-2 and 306-1). In other examples, interconnects 501 are implemented across a different number of layers.

In addition to the CLK and AVDD signals provided by the interconnects 501, the DAC modules 502 also require access to the GND, REF-M, REF-P, and the data itself before conversion operations can be performed. In this example, the DAC modules 502 receive both the GND and REF-M signals by using short, vertical interconnects that are in contact with the GND/REF-M plane 402 as described above. In some examples, the foregoing short, vertical interconnects are referred to as vias.

The REF-P circuitry 504 generate the REF-P voltage and provide the voltage to the nearest DAC modules 502. For example, some interconnects couple the REF-P circuitry 504A to the interconnects 502-5, 502-6, 502-7, and 502-8, other interconnects couple the REF-P circuitry 504B to the interconnects 502-9, 502-10, 502-11, and 502-12, etc. The REF-P circuits 504 can be implemented nearby and in the same layer as the DAC modules 502 because the circular pattern of the radial architecture creates space adjacent to the perimeter of the circle that is unlikely to be used for a different purpose.

Moreover, REF-P circuits cannot be implemented adjacent to the DAC modules 210 in the IC 204 because due to the density of the surrounding interconnect tree structures. The adjacent positioning of the REF-P circuits reduces the parasitic capacitance on the interconnects 501D that carry the CLK signals, thereby reducing the power consumption of the interconnects 501D by 25% compared to the interconnect tree structure that carries CLK signals in the known linear architecture. The reduced parasitic capacitance also improves the rise time and fall time of signal updates in the IC 300 by approximately 50% when compared to the rise time and fall time of the same signal updates as implemented on the IC 204. The improved rise and fall times also decrease the dynamic error caused by mismatch from latch operations within the DAC modules, thereby reducing the power consumption by 30% in the subsequent blocks.

In the example of FIGS. 5A and 5B, there are sixteen DAC modules 502 that collectively form the fourteen-bit interleaved DAC circuitry 108. More generally, the radial architecture described in examples herein may be implemented by two or more conversion circuits of any number and any kind. To do so, the interconnects 501 may distribute to and/from the center point (x=0 y=0) in more than four directions. Also or alternatively, the IC 300 be implemented with a greater number of conversion circuits (for example, DAC modules or ADC modules) off each branch of the interconnects. In either of the foregoing example, the IC 300 still implements a radial architecture and improves performance as described above provided that a) the conversion circuits are still positioned symmetrically around a center point in both the x and y dimensions and b) the interconnects 501 are still the same length from the center point to each of the conversion circuits.

Notably, the interconnects 501B and 501C are individually rated to only support a portion of the total current produced by the DAC modules 502. For example, in FIG. 5B, the interconnects 501B that carry the AN-P and AN-M signals from the DAC modules 502-3, 502-4,502-5, and 502-6 only support ¼ of the total current that exits the IC 300 on the interconnects 406. Thus, the interconnects 406 are comparatively wide to support the full current of the final AN-P and AN-M signals, the interconnects 501B and 501C are comparatively narrow because they individually carry only a portion of the final AN-P and AN-M signals. In contrast, the linear architecture of FIG. 2 requires comparatively wide interconnects (for example, at least the same width as the interconnects 406) across the entire 400 μm span of the DAC modules 210 to carry the full AN-P and AN-M signals. Therefore, example radial architecture reduces the amount of metal needed to carry the analog current signals compared to the known linear architecture.

FIG. 6 is a top-down view of the thin layer 304-1 of the example IC 300 of FIG. 3. FIG. 6 shows an example region 600 of the thin-layer 304-1. The region 600 includes example clock buffer circuitry 602 and example decoupling capacitor (decap) circuitry 604.

Like the clock buffers described in FIG. 2, the clock buffer circuitry 602 distributes multiple copies of a signal at its outputs and mitigates against factors that degrade signal quality (for example, parasitic capacitance) that increase proportionally with transmission distance. In this example, the clock buffer circuitry 602 receives the CLK-P and CLK-M signals from system level circuitry within the device 100 and distributes the signals to the DAC modules 502 via the interconnects 501D.

Notably, the region 600 on the thin layer 304-1 is implemented beneath the start point of the interconnects 501A and 501D (and the end point of the interconnects 501B and 501C) shown in FIG. 5B. Thus, the interconnects 501D can couple to the clock buffer circuitry 602 without interfering the symmetric routing of the interconnects 501A-501C used in the radial architecture.

The decap circuitry 604 suppresses high frequency noise from a power supply of the device 100 and prevents voltage fluctuations. Thus, circuit architectures generally include a decoupling capacitor wherever a CLK buffer is implemented.

In FIG. 2, the signal path from the CLK signals to a DAC module 210-1 requires three clock buffer circuits to implement because the path has a length of 600 μm. Moreover, the design of the linear architecture requires seven CLK buffer circuits throughout the interconnect tree structure to distribute the CLK signals to the DAC modules 210. Thus, the linear architecture also requires at least seven decoupling capacitors (decap circuits) to mitigate the noise caused by the seven CLK buffer circuits. In contrast, the example radial architecture described herein needs only one CLK buffer circuitry 602 and one decap circuitry 604 because the signal path from the CLK buffer circuitry 602 to the DAC modules 502 is only 110 μm.

The reduced signal path length of the example radial architecture compared to the known linear architecture provides numerous advantages. For example, the reduced signal path length enables the interconnects 501 of FIGS. 5A and 5B to be implemented with approximately 50% less parasitic capacitance than the interconnect tree structures of FIG. 2. In turn, the IC 300 can be implemented with fewer CLK buffer circuits and decap circuits than the IC 204, as shown in FIG. 6. The reduction of the foregoing circuitry instances and the close proximity of the DAC modules 502 to the center point enables the radial architecture to be implemented with approximately 25% less space on an IC than a linear architecture and still perform the same DAC operations.

The reduced signals path length also enables the example radial architecture to exhibit approximately 50% less dynamic error caused by routing mismatch than the known linear architecture. Similarly, gradient mismatch across the DAC modules 502 is approximately 25% less than the gradient mismatch in the DAC modules 210 due to the decreased physical distance between any two DAC modules 502. Furthermore, because the dynamic error of the radial architecture described herein is significantly reduced in comparison to the known linear architecture, devices that receive the analog current signals produced by the IC 300 do not need to perform dynamic correction in the digital domain. The lack of digital dynamic correction contributes an additional 56% power reduction compared to the known linear architecture.

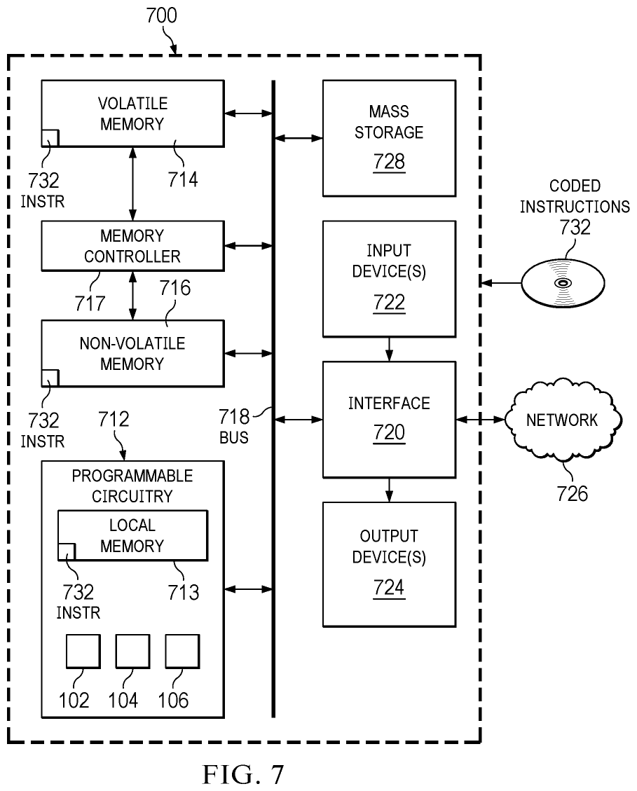

FIG. 7 is a block diagram of an example programmable circuitry platform 700 structured to one or a combination of execute or instantiate one or more of machine-readable instructions or operations to implement the device 100 of FIG. 1. The programmable circuitry platform 700 can be, for example, a server, a personal computer, a workstation, a self-learning machine (for example, a neural network), a mobile device (for example, a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (for example, an augmented reality (AR) headset, a virtual reality (VR) headset, etc.) or other wearable device, or any other type of computing or electronic device.

The programmable circuitry platform 700 of the illustrated example includes programmable circuitry 712. The programmable circuitry 712 of the illustrated example is hardware. For example, the programmable circuitry 712 can be implemented by one or more integrated circuits, logic circuits, FPGAs, microprocessors, CPUs, GPUs, DSPs, or microcontrollers from any desired family or manufacturer. The programmable circuitry 712 may be implemented by one or more semiconductor based (for example, silicon based) devices. In this example, the programmable circuitry 712 implements the digital circuitry 102, the format circuitry 104, and the cancellation circuitry 106.

The programmable circuitry 712 of the illustrated example includes a local memory 713 (for example, a cache, registers, etc.). The programmable circuitry 712 of the illustrated example is in communication with main memory 714, 716, which includes a volatile memory 714 and a non-volatile memory 716, by a bus 718. The volatile memory 714 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 716 may be implemented by one or a combination of flash memory or any other desired type of memory device. Access to the main memory 714, 716 of the illustrated example is controlled by a memory controller 717. In some examples, the memory controller 717 may be implemented by one or more integrated circuits, logic circuits, microcontrollers from any desired family or manufacturer, or any other type of circuitry to manage the flow of data going to and from the main memory 714, 716.

The programmable circuitry platform 700 of the illustrated example also includes interface circuitry 720. The interface circuitry 720 may be implemented by hardware in compliance with any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 722 are connected to the interface circuitry 720. The input device(s) 722 permit(s) a user (for example, a human user, a machine user, etc.) to enter one of or a combination of data or commands into the programmable circuitry 712. The input device(s) 722 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 724 are also connected to the interface circuitry 720 of the illustrated example. The output device(s) 724 can be implemented, for example, by one of or a combination of display devices (for example, a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 720 of the illustrated example, thus, includes one of or a combination of a graphics driver card, a graphics driver chip, or graphics processor circuitry such as a GPU.

The interface circuitry 720 of the illustrated example also includes a communication device such as one of or a combination of a transmitter, a receiver, a transceiver, a modem, a residential gateway, a wireless access point, or a network interface to facilitate exchange of data with external machines (for example, computing devices of any kind) by a network 726. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 700 of the illustrated example also includes one or more mass storage discs or devices 728 to store one or more of firmware, software, or data. Examples of such mass storage discs or devices 728 include one or more magnetic storage devices (for example, floppy disk, drives, HDDs, etc.), optical storage devices (for example, Blu-ray disks, CDs, DVDs, etc.), RAID systems, or solid-state storage discs or devices such as flash memory devices and SSDs.

The machine-readable instructions 732 may be stored in one of or a combination of the mass storage device 728, in the volatile memory 714, in the non-volatile memory 716, or on at least one non-transitory computer readable storage medium such as a CD or DVD which may be removable.

“Including” and “comprising” (and all forms and tenses thereof) are used herein to be open ended terms. Thus, whenever a claim employs any form of “include” or “comprise” (for example, comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (for example, “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, for example, the same entity or object. Also, although individual features may be included in different examples or claims, these may possibly be combined, and the inclusion in different examples or claims does not imply that a combination of features is at least one of not feasible or advantageous.

As used herein, connection references (for example, attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (for example, within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (for example, wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (for example, an application specific circuit (ASIC)) structured to perform specific operation(s) and including one or more semiconductor-based logic devices (for example, electrical hardware implemented by one or more transistors), or (ii) one or more general purpose semiconductor-based electrical circuits programmable with instructions to perform one or more specific functions(s) or operation(s) and including one or more semiconductor-based logic devices (for example, electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (for example, one or more FPGAs, one or more CPUs, one or more GPUs, one or more NPUs, one or more DSPs, etc., and any combination(s) thereof), and orchestration technology (for example, application programming interface(s) (API(s)) that may assign computing task(s) to whichever one(s) of the multiple types of programmable circuitry is/are suited and available to perform the computing task(s).

A device that is “configured to” perform a task or function may be configured (for example, at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (for example, at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described that improve performance, reduce cost, and reduce power consumption of interleaved conversion circuitry. Described systems, apparatus, articles of manufacture, and methods improve the efficiency of using a computing device by implementing a radial architecture in which the conversion modules are placed equidistant from a center point using a circle pattern such that interconnects travelling from the center point to a first module are the same length as interconnects travelling from the center point to a second module. The example radial architecture removes the need to route signals using interconnect tree structures, thereby freeing space in the integrated circuit for REF-P circuits adjacent to the conversion modules and a GND/REF-M plane over the conversion modules. The example radial architecture described herein reduces the signal path length compared to known linear architecture. These changes reduce the dynamic error, the cost, and the power consumption of an IC that implements interleaved conversion circuitry using the example radial architecture. Described systems, apparatus, articles of manufacture, and methods are also directed to one or more improvement(s) in the operation of a machine such as a computer or other electronic, electromechanical, or mechanical device.

What is claimed is:

1. An integrated circuit comprising:
two or more conversion circuits that are implemented on one layer of the integrated circuit in a circular pattern around a center point of the layer; and
interconnects between the two or more conversion circuits and the center point.

2. The integrated circuit of claim 1, wherein the two or more conversion circuits are implemented symmetrically around the center point in the circular pattern.

3. The integrated circuit of claim 1, wherein the two or more conversion circuits collectively form interleaved Analog to Digital Conversion (ADC) circuitry.

4. The integrated circuit of claim 1, wherein the two or more conversion circuits collectively form interleaved Digital to Analog Conversion (DAC) circuitry.

5. The integrated circuit of claim 1, wherein:
the layer that implements the two or more conversion circuits is a first layer;
the integrated circuit further includes a second layer beneath the first layer; and
the integrated circuit further includes buffer circuitry implemented on the second layer, wherein two or more of the interconnects couple the buffer circuitry to the two or more conversion circuits through the center point of the first layer.

6. The integrated circuit of claim 5, wherein the second layer is less thick than the first layer.

7. The integrated circuit of claim 1, wherein:
the interconnects include first interconnects and second interconnects; and
the two or more conversion circuits have inputs coupled to the first interconnects, wherein each of the first interconnects travel a same distance from the center point to the two or more conversion circuits; and
the two or more conversion circuits have outputs coupled to the second interconnects, wherein each of the second interconnects travel the same distance from the two or more conversion circuits to the center point.

8. The integrated circuit of claim 7, wherein the first interconnects are configured to carry a differential clock signal and a supply voltage to the two or more conversion circuits.

9. The integrated circuit of claim 7, wherein the second interconnects are configured to carry a differential analog current signal, and a differential cancellation signal from the two or more conversion circuits.

10. The integrated circuit of claim 9, wherein the second interconnects are individually rated to only support a portion of a total current produced by the two or more conversion circuits.

11. An integrated circuit comprising:
a ground plane on a first layer of the integrated circuit;
two or more conversion circuits that are implemented on a second layer of the integrated circuit in a circular pattern around a center point of the second layer, the second layer beneath the first layer; and
interconnects between the two or more conversion circuits and the center point.

12. The integrated circuit of claim 11, further including vias that connect the two or more conversion circuits to the ground plane.

13. The integrated circuit of claim 11, further including:
circuits on the second layer that are configured to generate a first portion of a differential reference signal, the circuits located adjacent to a perimeter of the circular pattern; and
interconnects that couple the circuits to the two or more conversion circuits.

14. The integrated circuit of claim 13, wherein the two or more conversion circuits are configured to use a voltage from the ground plane as both a ground signal and a second portion of the differential reference signal.

15. The integrated circuit of claim 11, wherein:
the interconnects are first interconnects; and
the integrated circuit further includes second interconnects that couple outputs of the two or more conversion circuits to outputs of the integrated circuit, wherein the second interconnects are implemented in the first layer but electrically isolated from the ground plane.

16. The integrated circuit of claim 11, wherein the two or more conversion circuits collectively form interleaved Digital to Analog Conversion (DAC) circuitry.

17. An apparatus comprising:
digital circuitry configured to produce first digital data;
format circuitry configured to change the first digital data from a binary format to a thermometric format;
cancellation circuitry configured to produce second digital data that a) does not have a bit transition wherever the first digital data does have a bit transition and b) does contain a bit transition wherever the first digital data does not have a bit transition; and
interleaved Digital to Analog Conversion (DAC) circuitry configured to convert the first digital data and the second digital data into analog current signals, wherein the interleaved DAC circuitry is implemented on an integrated circuit that includes:
two or more conversion circuits implemented on one layer of the integrated circuit in a circular pattern around a center point of the layer; and
interconnects between the two or more conversion circuits and the center point.

18. The apparatus of claim 17, wherein the two or more conversion circuits are implemented symmetrically around the center point in the circular pattern.

19. The apparatus of claim 17, wherein:
the layer that implements the two or more conversion circuits is a first layer;
the integrated circuit further includes a second layer beneath the first layer; and
the integrated circuit further includes buffer circuitry implemented on the second layer, wherein two or more of the interconnects couple the buffer circuitry to the two or more conversion circuits through the center point of the first layer.

20. The apparatus of claim 17, wherein:
the interconnects include first interconnects and second interconnects; and
the two or more conversion circuits have inputs coupled to the first interconnects, wherein each of the first interconnects travel a same distance from the center point to the two or more conversion circuits; and
the two or more conversion circuits have outputs coupled to the second interconnects, wherein each of the second interconnects travel the same distance from the two or more conversion circuits to the center point.
